(19) United States
(12) Patent Application Publication
(10) Pub. No.: US 2014/0376177 A1
(43) Pub. Date: Dec. 25, 2014

(54) SERVER WITH A FUNCTION OF GENERATING FAN TABLE AND METHOD FOR GENERATING FAN TABLE

(71) Applicant: HON HAI PRECISION CO., LTD., New Taipei (TW)

(72) Inventor: HSUAN-I LIN, New Taipei (TW)

(21) Appl. No.: 14/314,270

(22) Filed: Jun. 25, 2014

(30) Foreign Application Priority Data
Jun. 25, 2013 (TW) 102122508

(51) Int. Cl. H05K 7/20; G05D 23/19

(52) U.S. Cl. CPC H05K 7/20736; G05D 23/19
USPC 361/679.48

(57) ABSTRACT

A method for generating a fan table includes the following. A temperature of each electronic component and a speed of a fan are obtained at preset intervals, The obtained temperature of each electronic component is compared with the corresponding preset temperature. In addition, the speed and a corresponding combination of loads are recorded to a fan table of the electronic component when the temperature of the electronic component is equal to the corresponding present temperature.

### CROSS-REFERENCE TO RELATED APPLICATIONS

This application claims priority to Taiwanese Patent Application No. 102122508 filed on Jun. 25, 2013 in the Taiwan Intellectual Property Office, the contents of which are incorporated by reference herein.

### FIELD

The present disclosure relates to servers, and particularly to a server with a function of generating a fan table, and a method thereof.

### BACKGROUND

Servers are generally required to support a great number of electronic components, such as central processing units, storage devices, hard disk drives, program storage units, and PCI cards. A heat dissipation test of each electronic component is needed, and then a corresponding fan speed is designed for each electronic component to maintain that the temperature of the corresponding electronic component is at a preset value at any load combination. In addition, a fan table is generated to include the corresponding fan speeds of all electronic components and the corresponding load combinations.

### BRIEF DESCRIPTION OF THE DRAWINGS

Implementations of the present technology will now be described, by way of example only, with reference to the attached figures.

FIG. 1 is a block diagram of a server.

FIG. 2 is a flowchart diagram of an embodiment of a method for generating a fan table.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “comprising” means “including, but not necessarily limited to”; it specifically indicates open-ended inclusion or membership in a so-described combination, group, series and the like.

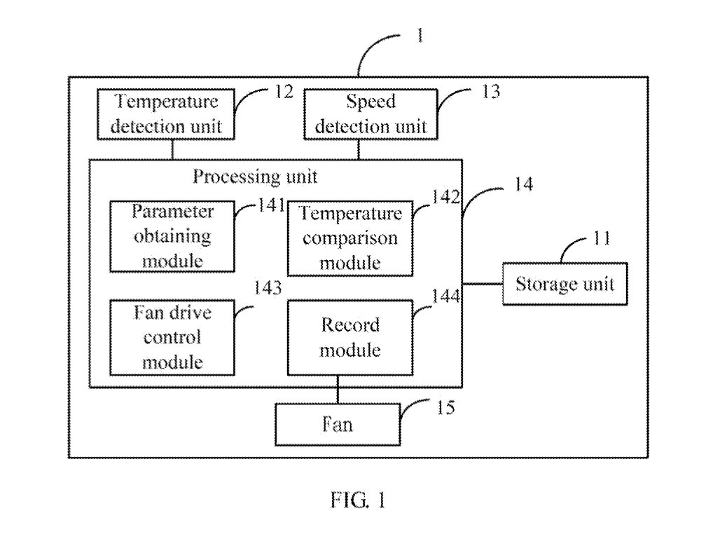

FIG. 1 illustrates a server 1 of the present disclosure. The server 1 can include a storage unit 11, a temperature detection unit 12, a speed detection unit 13, a processing unit 14, and a fan 15. FIG. 1 only shows one fan, however, the number of the fans 15 is not limited to one.

The server 1 can further include a combination of loads (not shown). The combination of loads can include a number of electronic components (not shown), such as a CPU, a memory, and a hard drive. In detail, each electronic component can generate heat when working, so the combination of the generated heat of a combination of loads such as a CPU, a memory, and a hard drive is less than the level of the generated heat of a combination of loads such as a CPU, two memory chips, and two hard drives. Each electronic component such as a CPU, should maintain to a preset temperature value or a preset temperature range, so the fan 15 requires different speeds in different combinations of loads.

The storage unit 11 can store a number of preset temperatures respectively corresponding to the electronic components, and a number of fan tables respectively corresponding to the electronic components and fan settings. In the embodiment, the fan table of each electronic component can include a number of fan speeds to maintain the temperature of the electronic component at the corresponding preset temperature when the electronic component has different combinations of loads. Each electronic component has a corresponding fan table.

The temperature detection unit 12 is used to detect a temperature T1 of each electronic component.

The speed detection unit 13 is used to detect a speed V1 of the fan 15.

The processing unit 14 has one or more processors. The processing unit 14 is used to execute instructions stored in modules on the storage unit 11 and the modules can include a parameter obtaining module 141, a temperature comparison module 142, a fan drive control module 143, and a recording module 144. The processing unit 14 can be a digital signal processor, a single chip, or a central processing unit. The storage unit 11 can be a hard disk, a flash memory, a compact disk, and so on.

The parameter obtaining module 141 is used to obtain the temperature T1 of each electronic component detected by the temperature detection unit 12 and the speed V1 of the fan 15 detected by the speed detection unit 13 at intervals.

The temperature comparison module 142 is used to compare the obtained temperature T1 of each electronic component with the preset temperature of the corresponding electronic component.

The fan drive control module 143 is used to increase the speed V1 of the fan 15 to an adjusted speed V2 when the temperature comparison module 142 compares that the obtained temperature T1 is greater than the preset temperature. The fan drive control module 143 is further used to decrease the speed V1 of the fan 15 to the adjusted speed V2 when the temperature comparison module 142 compares the obtained temperature T1 is less than the preset temperature.

The recording module 144 is used to record the speed V1 and the corresponding combination of loads to the fan table of the electronic component when the temperature comparison module 12 determines the temperature of the electronic component is equal to the preset temperature of the electronic component.

In the embodiment, the temperature comparison module 12 further calculates a difference value Tx between a temperature T1 of each electronic component and the corresponding preset temperature T0. The fan drive control module 143 further controls an increase or decrease of the speed of the fan 15 by using a larger adjustment unit, such as 10 revolutions per second (rps), when the difference value Tx is greater than a predetermined value. The fan drive control module 143 further controls the increase or decrease of the speed of the fan 15 by using a smaller adjustment unit (such as 1 rps) when the difference value Tx is less than the predetermined value.

In one embodiment, the temperature T1 is 40° C. and the preset temperature is 30° C., and the predetermined value is 5° C. The difference value Tx calculated by the temperature comparison module 12 is 10° C. and is greater than the predetermined value. The fan drive control module 143 then controls the speed of the fan 15 to increase by using the larger adjustment unit. If the temperature T1 is 32° C., then the difference value Tx calculated by the temperature comparison module 12 is 2° C. and is less than the predetermined value. The fan drive control module 143 then controls the speed of the fan 15 to decrease by using the smaller adjustment unit.

In the embodiment, after the fan drive control module 143 controls the fan 15 to rotate with the adjusted speed V2 for a predetermined time, the temperature comparison module 142 compares the temperature T1 to the preset temperature TO again. When the temperature T1 is greater than the preset temperature TO, the fan drive control module 143 increases the speed V1 of the fan 15 to the speed V2 and controls the fan 15 to rotate with the adjusted/increased speed V2 for the predetermined time. When the temperature T1 is less than the preset temperature T0, the fan drive control module 143 decreases the speed V1 of the fan 15 to the speed V2 and controls the fan 15 to rotate with the decreased speed V2 for the predetermined time. Therefore, the fan drive control module 143 and the temperature comparison module 142 execute the above steps repeatedly until the temperature T1 is equal to the preset temperature T0. In addition, the recording module 144 records the speed V1 when the temperature T1 is equal to the preset temperature T0 and the corresponding combination of loads to the fan table of the electronic component accordingly.

The fan speed of the electronic component in other combinations of loads can be tested according to the methods described above, and the recording module 144 records the speed V1 of when the temperature T1 is equal to the preset temperature T0 and the other combinations of loads to the fan table of the electronic component accordingly.

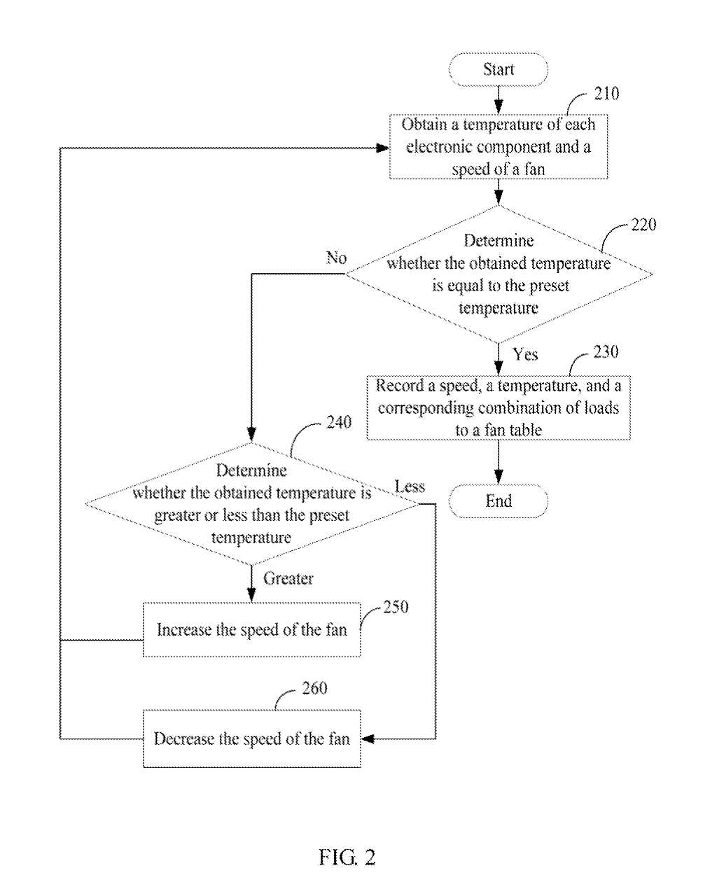

FIG. 2 illustrates a flowchart of a method for generating a fan table. In block 210, a parameter obtaining module obtains a temperature of each electronic component and a speed of a fan. In detail, the parameter obtaining module obtains the temperature of each electronic component detected by a temperature detection unit and the speed of the fan detected by a speed detection unit at intervals

In block 220, a temperature comparison module compares the obtained temperature of each electronic component to a preset temperature of the corresponding electronic component, and determines whether the obtained temperature is equal to the preset temperature. If yes, the process continues to block 230; if no, the process continues to block 240.

In block 230, a recording module records a speed, a temperature, and a corresponding combination of loads to a fan table.

In block 240, the temperature comparison module determines whether the obtained temperature is greater or less than the preset temperature. If greater, the process continues to block 250; if less, the process continues to block 260.

In block 250, a fan drive control module increases the speed of the fan to an adjusted speed, controlling the fan to rotate with the adjusted speed for a predetermined time, and then returns to block 210.

In block 260, the fan drive control module decreases the speed of the fan, controls the fan to rotate with the decreased speed for a predetermined time, and then returns to block 210.

The embodiments shown and described above are only examples. Many details are often found. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A server comprising:
a fan;
a temperature detection unit configured to detect a temperature of each electronic component of the server in real time;
a speed detection unit configured to detect a speed of the fan in real time;
a storage unit configured to store a plurality of preset temperatures respectively corresponding to the electronic components and a plurality of fan tables respectively corresponding to the electronic components;
a processing unit; and
a plurality of modules which are collections of instructions executed by the processing unit, the modules comprising:
a parameter obtaining module configured to obtain a temperature of each electronic component detected by the temperature detection unit and the speed of the fan detected by the speed detection unit at intervals;
a temperature comparison module configured to compare the obtained temperature of each electronic component with the preset temperature of the corresponding electronic component; and
a recording module configured to record the speed and a corresponding combination of loads to the fan table of the electronic component when the temperature comparison module determines the temperature of the electronic component is equal to the present temperature of the electronic component.

2. The server according to claim 1, wherein the modules further comprise a fan drive control module configured to increase the speed of the fan when the obtained temperature is greater than the preset temperature, and to decrease the speed of the fan when the obtained temperature is less than the preset temperature.

3. The server according to claim 2, wherein the temperature comparison module is further configured to calculate a difference value between the temperature and the corresponding preset temperature; the fan drive control module is further configured to increase or decrease the speed of the fan by using a larger adjustment unit when the difference value is greater than a predetermined value, and to increase or decrease the speed of the fan by using a smaller adjustment unit when the difference value is less than the predetermined value.

4. A method for generating a fan table comprising:
obtaining a temperature of each electronic component and a speed of a fan at intervals;
comparing the obtained temperature of each electronic component with the corresponding preset temperature; and
recording the speed and a corresponding combination of loads to a fan table of the electronic component when the temperature of the electronic component is equal to the corresponding present temperature.

5. The method according to claim 4, further comprising:
increasing the speed of the fan when the obtained temperature is greater than the preset temperature; and
decreasing the speed of the fan when the obtained temperature is less than the preset temperature.

6. The method according to claim 4, further comprising:
calculating a difference value between the temperature and the corresponding preset temperature;
increasing or decreasing the speed of the fan by using a larger adjustment unit when the difference value is greater than a predetermined value; and
increasing or decreasing the speed of the fan by using a smaller adjustment unit when the difference value is less than the predetermined value.

7. A server comprising:
a plurality of electronic components;
a temperature detection unit configured to detect a temperature of each of the plurality of electronic components;
a speed detection unit configured to detect, in real time, a speed of a fan;
a storage unit configured to store a plurality of preset temperatures and a plurality of fan settings, wherein each of the preset temperatures corresponds to one of the plurality of electronic components;
a processing unit having one or more processors, the processing unit configured to execute instructions stored in modules on the storage unit and the modules comprise:
a parameter obtaining module configured to obtain a temperature of each of the plurality of electronic components detected by the temperature detection unit and the speed of the fan detected by the speed detection device at intervals;
a temperature comparison module configured to compare the obtained temperature of each of the plurality of electronic components with the preset temperature of corresponding electronic component;
a recording module configured to record the speed and a corresponding combination of loads to the fan table of the electronic component when the temperature comparison module determine the temperature of the electronic component is equal to the present temperature.
